(19) United States
(12) Patent Application Publication
(10) Pub. No.: US 2025/0353284 A1
(43) Pub. Date: Nov. 20, 2025

(54) BONDING APPARATUS

(71) Applicant: Samsung Display Co., LTD., Yongin-si (KR)

(72) Inventors: Myung Hun OH, Yongin-si (KR); Byung Moo KIM, Yongin-si (KR); Sang Cheol KIM, Yongin-si (KR); Jun Hee LEE, Yongin-si (KR)

(21) Appl. No.: 19/058,333

(22) Filed: Feb. 20, 2025

(30) Foreign Application Priority Data
May 20, 2024 (KR) 10-2024-0065004

(51) Int. Cl. B32B 37/00; B30B 15/00; B30B 15/28

(52) U.S. Cl. CPC B32B 37/0046; B30B 15/0029; B30B 15/28

(57) ABSTRACT

A bonding apparatus includes an upper jig supporting an upper material, a movement module configured to move the upper jig in a vertical direction, a lower jig disposed below the upper jig and supporting a lower material, a support module supporting the lower jig, and an alignment module configured to support the lower jig and to move the lower jig so that the lower material is aligned on a lower side of the upper material, wherein the support module and the alignment module support the lower jig independently of each other.

This application claims priority to Korean Patent Application No. 10-2024-0065004, filed on May 20, 2024, and all the benefits accruing therefrom under 35 U.S.C. § 119, the content of which in its entirety is herein incorporated by reference.

### BACKGROUND

### 1. Field

The invention relates to a bonding apparatus.

### 2. Description of the Related Art

Display devices are becoming more and more important as multimedia technology evolves. Accordingly, a variety of types of display devices such as an organic light-emitting display (OLED) and a liquid-crystal display (LCD) are currently used. Such display devices find a variety of applications including mobile electronic devices, e.g., portable electronic devices such as smart phones, smart watches and tablet PCs.

The display device includes a display panel that displays images, and a cover window that is attached to the display panel and that protects the display panel. The cover window is attached to the display panel by a coupling agent interposed between the display panel and the cover window.

The display panel and the cover window may be attached by being pressed together using a bonding apparatus. Before the display panel and the cover window are attached together by the bonding apparatus, an alignment process may be performed to align the display panel with the cover window.

### SUMMARY

Aspects of the invention provide a bonding apparatus that can prevent excessive load from being applied to an alignment driver for aligning a lower material when an upper material and the lower material are attached together by way of distributing the load.

However, embodiments of the invention are not limited to those set forth herein. The above and other embodiments will become more apparent to one of ordinary skill in the art to which the invention pertains by referencing the detailed description of the present disclosure given below.

According an embodiment, a bonding apparatus includes an upper jig supporting an upper material, a movement module configured to move the upper jig in a vertical direction, a lower jig disposed below the upper jig and supporting a lower material, a support module supporting the lower jig, and an alignment module configured to support the lower jig and to move the lower jig so that the lower material is aligned on a lower side of the upper material, wherein the support module and the alignment module support the lower jig independently of each other.

In an embodiment, the support module includes a horizontal moving portion connected to a lower portion of the lower jig and configured to move the lower jig in a horizontal direction, and a first support plate supporting the horizontal moving portion.

In an embodiment, the horizontal moving portion includes a first rail disposed on an upper surface of the first support plate and extending in a first direction, a first block moved along the first rail, a second rail connected to the lower jig and extending in a second direction, and a second block moved along the second rail.

In an embodiment, the second block is disposed on an upper side of the first block, and the second rail is disposed on an upper side of the second block.

In an embodiment, the horizontal moving unit further includes a base member disposed between the first block and the second block.

In an embodiment, the second direction is directed orthogonal to the first direction.

In an embodiment, the horizontal moving portion further includes a rotating member disposed between the lower jig and the second rail, wherein the rotating member rotates the lower jig in the horizontal direction.

In an embodiment, the horizontal moving portion is connected to a center of the lower jig.

In an embodiment, the support module further includes at least one first support shaft connected to a lower portion of the first support plate and supporting the first support plate, a second support plate supporting the first support shaft, a third support plate connected to a lower portion of the second support plate and supporting the second support plate, and a fourth support plate supporting the third support plate.

In an embodiment, the support module further includes a second support shaft connected to the lower portion of the first support plate and an upper portion of the fourth support plate to support the first support plate.

In an embodiment, the second support shaft is connected to the lower portion of the first support plate on a lower side of the horizontal moving portion.

In an embodiment, the at least one first support shaft includes a plurality of first support shafts, wherein the plurality of first support shafts are connected to lower portions of both edges of the first support plate so that the second support shaft is located between the first support shafts.

In an embodiment, the alignment module includes at least one first alignment shaft connected to a lower portion of the lower jig and supporting the lower jig, and an alignment driver connected to the first alignment shaft to move the lower jig.

In an embodiment, the at least one first alignment shaft includes a plurality of first alignment shafts, wherein the plurality of first alignment shafts are connected to lower portions of both edges of the lower jig so that the support module is located between the first alignment shafts.

In an embodiment, the alignment module further includes a first alignment plate supporting the first alignment shaft, at least one second alignment shaft connected to a lower portion of the first alignment plate and supporting the first alignment plate, and a second alignment plate disposed above the alignment driver and supporting the second alignment shaft.

In an embodiment, the at least one second alignment shaft includes a plurality of second alignment shafts, wherein the plurality of second alignment shafts are connected along a lower position of edges of the first alignment plate.

In an embodiment, the alignment module further includes a damper disposed under the alignment driver.

In an embodiment, the alignment module further includes a third alignment plate disposed between the alignment driver and the damper to support the alignment driver.

In an embodiment, the support module is connected to a center of the lower jig, and the alignment module is connected to the lower portion of the lower jig such that the align module is spaced apart from the support module.

In an embodiment, the alignment module is connected to lower portions of edges of the lower jig.

According to an embodiment, it is possible to prevent damage to an alignment driver for aligning a lower material, when an upper material and the lower material are attached together, by preventing an excessive load from being applied to the alignment driver by way of distributing the load.

The effects according to an embodiment are not limited to those mentioned above and more various effects are included in the following description of the present disclosure.

### BRIEF DESCRIPTION OF THE DRAWINGS

The above and other aspects and features of the invention will become more apparent by describing in detail example embodiments thereof with reference to the attached drawings, in which:

FIG. 1 is a front view of a bonding apparatus, according to an embodiment.

FIG. 2 is a perspective view of the lower jig, the support module, and the alignment module of FIG. 1, according to an embodiment.

FIG. 3 is a front side view of the lower jig, the support module, and the alignment module of FIG. 2, according to an embodiment.

FIG. 4 is an enlarged view of area A of FIG. 2, according to an embodiment.

FIG. 5 is an enlarged view of area B of FIG. 3, according to an embodiment.

FIG. 6 is a perspective view showing a horizontal moving portion of the lower jig, the support module, and the alignment module of FIG. 2, according to an embodiment.

FIG. 7 is a perspective view of the lower jig, the support module, and the alignment module of FIG. 2 showing a state in which the lower material is seated on the lower jig of FIG. 2 and the upper material is positioned on the lower material, according to an embodiment.

FIG. 8 is a perspective view of the lower jig, the support module, and the alignment module of FIG. 2 showing a state in which the lower material is aligned on the lower side of the upper material by the alignment module in FIG. 7, according to an embodiment.

FIG. 9 is a perspective view of the lower jig, the support module, and the alignment module of FIG. 2 showing a state in which the upper material presses the lower material in FIG. 8, according to an embodiment.

FIG. 10 is a front view of the lower jig, the support module, and the alignment module of FIG. 2 showing a state in which the load generated by being pressed by the upper material in FIG. 9 is distributed, according to an embodiment.

### DETAILED DESCRIPTION

Advantages and features of the invention and methods to achieve them will become apparent from the descriptions of example embodiments hereinbelow with reference to the accompanying drawings. However, the invention is not limited to example embodiments disclosed herein but may be implemented in various different ways. The example embodiments are provided for making the disclosure of the invention thorough and for fully conveying the scope of the invention to those skilled in the art.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the invention.

Features of various example embodiments of the invention may be combined partially or totally. As will be clearly appreciated by those skilled in the art, technically various interactions and operations are possible. Various example embodiments can be practiced individually or in combination.

Hereinafter, example embodiments of the invention will be described in detail with reference to the accompanying drawings.

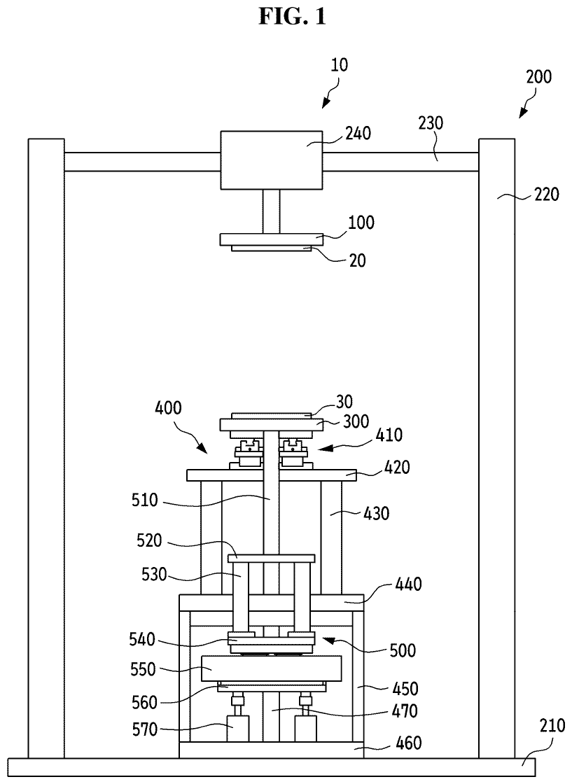

FIG. 1 is a front view showing a bonding apparatus 10, according to an embodiment.

In an embodiment and referring to FIG. 1, the bonding apparatus device 10 may attach an upper material 20 and a lower material 30 together, where the bonding apparatus 10 may include an upper jig 100, a movement module 200, a lower jig 300, a support module 400, and an alignment module 500.

In an embodiment, the upper jig 100 may support the upper material 20. For example, the upper jig 100 may support the upper material 20 by fixing the upper material 20 so that it does not move on the lower surface of the upper jig 100. The upper jig 100 may be provided as an electrostatic chuck using electrostatic force or a porous chuck using vacuum adsorption force.

In an embodiment, the movement module 200 may move the upper jig 100 in the vertical direction, where the movement module 200 may include a base plate 210, a moving portion 220, a connecting member 230, and an actuator 240.

In an embodiment, the base plate 210 may support at least one of the upper jig 100, the moving portion 220, the connecting member 230, the actuator 240, the lower jig 300, the support module 400, and the alignment module 500. For example, on the upper surface of the base plate 210, one or more of the upper jig 100, the moving portion 220, the connecting member 230, the actuator 240, the lower jig 300, the support module 400 and the alignment module 500 may be disposed and supported by the base plate 210. The base plate 210 may be provided as a plate having a predetermined thickness.

In an embodiment, the moving portion 220 may move the upper jig 100 in the vertical direction and may be disposed on the upper surface of the base plate 210. There may be a plurality of moving portions 220 spaced apart from each other. The upper jig 100 may be disposed between the plurality of moving portions 220, and the upper jig 100 may be connected to the moving portions 220 by the connecting member 230. The moving portions 220 may be rails extending upward from the upper surface of the base plate 210.

In an embodiment, the connecting member 230 may connect the upper jig 100 with the moving portion 220. For example, the connecting member 230 may be connected to the upper jig 100 by being connected to the actuator 240 connected to the upper jig 100. The connecting member 230 may be moved in the vertical direction along the moving portions 220, and accordingly the upper jig 100 may be moved in the vertical direction.

In an embodiment, the actuator 240 may be disposed above the upper jig 100 to move the upper jig 100 in the vertical direction. For example, the actuator 240 may be provided as a cylinder having a drive shaft. The drive shaft of the cylinder may be connected to the upper surface of the upper jig 100 so that the upper jig 100 may be moved in the vertical direction by the operation of the cylinder. The actuator 240 may provide pressing force onto the lower material 30 for attaching the upper material 20 to the lower material 30.

In an embodiment, the lower jig 300 may support the lower material 30. For example, the lower jig 300 may support the lower material 30 by fixing the lower material 30 so that it does not move on the upper surface of the lower jig 300. The lower jig 300 may be provided as an electrostatic chuck using electrostatic force or a porous chuck using vacuum adsorption force. The lower jig 300 may be disposed directly below the upper jig 100 and may be supported by the support module 400 and the alignment module 500.

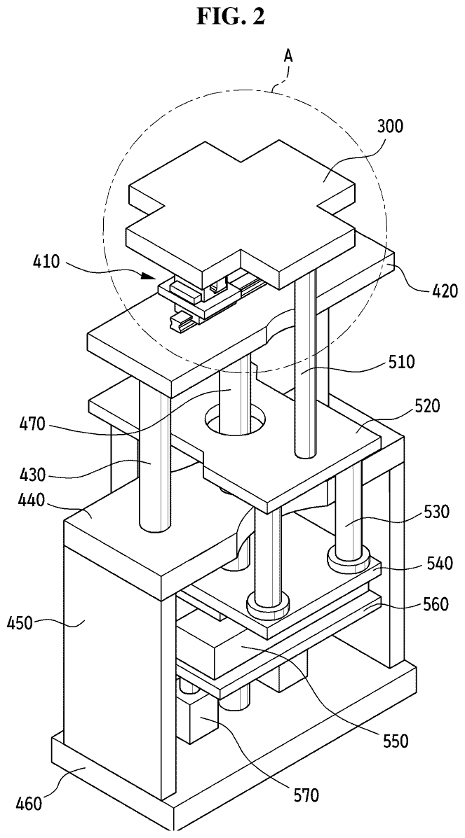

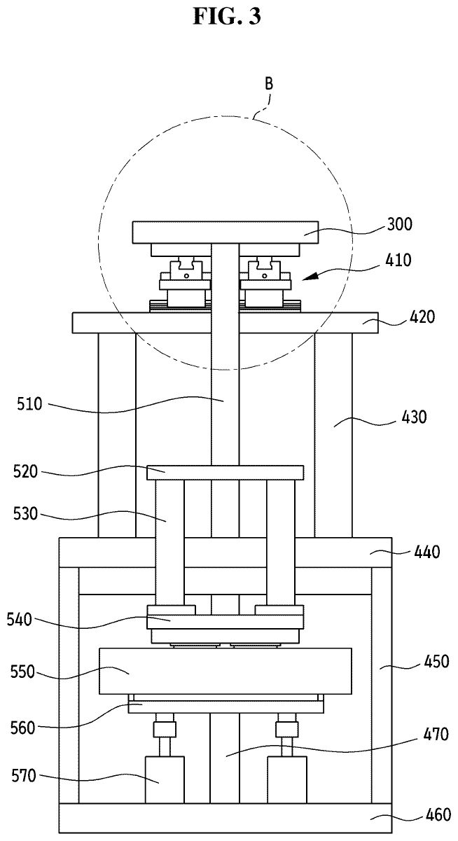

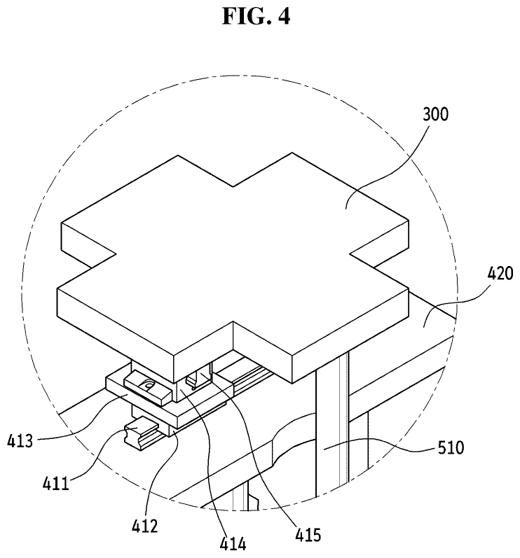

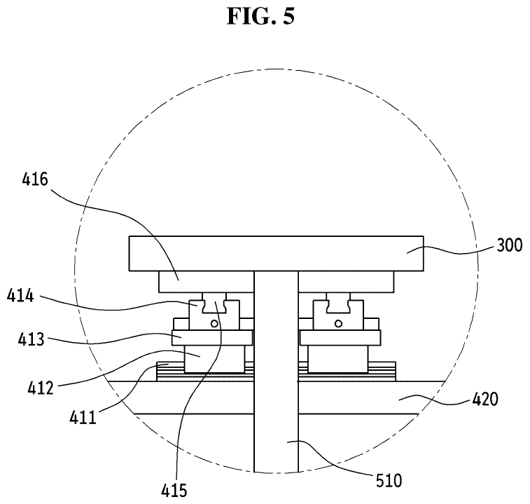

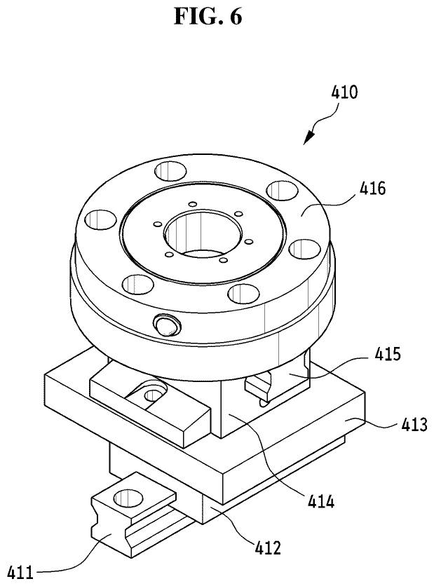

FIG. 2 is a perspective view showing the lower jig, the support module, and the alignment module of FIG. 1, according to an embodiment. FIG. 3 is a front view showing the front side of the lower jig, the support module, and the alignment of FIG. 2, according to an embodiment. FIG. 4 is an enlarged view of area A of FIG. 2, according to an embodiment. FIG. 5 is an enlarged view of area B of FIG. 3, according to an embodiment. FIG. 6 is a perspective view showing a horizontal moving portion of FIG. 2, according to an embodiment.

In an embodiment and referring to FIGS. 2 to 6, the support module 400 may be disposed under the lower jig 300 to support the lower jig 300. The support module 400 may include a horizontal moving portion 410, a first support plate 420, a first support shaft 430, a second support plate 440, a third support plate 450, a fourth support plate 460, and a second support shaft 470.

In an embodiment, the horizontal moving portion 410 may be connected to the lower portion of the lower jig 300 and may move the lower jig 300 in the horizontal direction. The horizontal moving portion 410 may be disposed on the first support plate 420 and supported by the first support plate 420. In other words, the horizontal moving portion 410 may be disposed between the lower jig 300 and the first support plate 420 so that the upper portion is connected to the lower jig 300 and the lower portion is connected to the first support plate 420. The horizontal moving portion 410 may be connected to the center of the lower jig 300. The horizontal moving portion 410 may include a first rail 411, a first block 412, a base member 413, a second block 414, a second rail 415, and a rotating member 416.

In an embodiment, the first rail 411 may be disposed on the upper surface of the first support plate 420 and may be extended from the upper surface of the first support plate 420 in a first direction. The first rail 411 may provide a path along which the first block 412 moves.

In an embodiment, the first block 412 may be moved along the first rail 411. In other words, the first block 412 may be moved in the first direction along the first rail 411. A rail groove may be formed in the lower surface of the first block 412, into which the first rail 411 fits. The first block 412 may be disposed on the upper side of the first rail 411 as the first rail 411 fits into the rail groove.

In an embodiment, the base member 413 may be disposed on the upper side of the first block 412 and may be provided as a plate with a predetermined thickness, and its lower surface may be connected to the upper surface of the first block 412. The second block 414 may be disposed on the upper surface of the base member 413.

In an embodiment, the second block 414 may be disposed on the upper side of the base member 413. In other words, the lower surface of the second block 414 may be connected to the upper surface of the base member 413. The second block 414 may be fixed to the upper side of the first block 412 by the base member 413. A rail groove may be formed in the upper surface of the second block 414 in the second direction, into which the second rail 415 fits. The second direction may be directed orthogonal to the first direction.

In an embodiment, the second rail 415 may be disposed on the upper side of the second block 414. In other words, the second rail 415 may be disposed on the upper side of the second block 414 as the second rail fits into the rail groove formed in the upper surface of the second block 414. The second rail 415 may be extended in the second direction to fit into the rail groove of the second block 414 and may be moved along the rail groove of the second block 414.

Although the second rail 415 is disposed on the upper side of the second block 414 and the second rail 415 is moved along the rail groove of the second block 414 according to this embodiment, the invention is not limited thereto. The second rail 415 is disposed on the upper side of the base member 413 to be extended in the second direction, and the second block 414 may be moved along the second rail 415.

In an embodiment, the rotating member 416 may be disposed between the lower jig 300 and the second rail 415 to rotate the lower jig 300 in the horizontal direction. In other words, the upper surface of the rotating member 416 may be connected to the center of the lower surface of the lower jig 300, and the lower surface may be connected to the upper surface of the second rail 415. The rotating member 416 may include an inner bearing and an outer bearing, where the inner bearing may be fixed to the second rail 415, and the outer bearing may be fixed to the lower jig 300, so that the lower jig 300 may be rotated in the horizontal direction as the outer bearing rotates.

In an embodiment, the above-described horizontal moving portion 410 may give a degree of freedom in the horizontal direction to the lower jig 300 so that the lower jig 300 may be moved by the alignment module 500. In other words, the lower jig 300 can have a degree of freedom in the first direction by the first rail 411 and the first block 412 and can have a degree of freedom in the second direction by the second block 414 and the second rail 415. In addition, the lower jig 300 can have a rotational degree of freedom in the horizontal direction by the rotating member 416.

In an embodiment, there may be a plurality of horizontal moving portions 410, where each of the plurality of horizontal moving portions 410 may include a first horizontal moving portion and a second horizontal moving portion. The first horizontal moving portion and the second horizontal moving portion may be disposed close to the center of the lower jig 300 such that they are spaced apart from each other.

In an embodiment, the first support plate 420 may be disposed under the horizontal moving portions 410 to support the horizontal moving portions 410. In other words, the first rail 411 may be fixed to the upper surface of the first support plate 420. The first support plate 420 may be provided as a plate extending in the first direction with a predetermined thickness, and the horizontal moving portions 410 may be disposed near the center of the first support plate 420.

In an embodiment, the first support shaft 430 may be connected to the lower surface of the first support plate 420 and support the first support plate 420. The first support shaft 430 may be provided as a circular rod with a predetermined diameter, and the upper end may be connected to the lower surface of the first support plate 420. In other words, the first support shaft 430 may be extended downward from the lower surface of the first support plate 420. There may be a plurality of first support shafts 430, where the plurality of first support shafts 430 may be connected to the lower surfaces of the both ends of the first support plate 420, respectively. The plurality of first support shafts 430 may be connected to the lower surfaces of both ends of the first support plate 420 in the second direction.

In an embodiment, the second support plate 440 may be disposed under the first support shafts 430 to support the first support shafts 430. In other words, the lower end of the first support shaft 430 may be fixed to the upper surface of the second support plate 440. The second support plate 440 may be provided as a plate extending in the first direction with a predetermined thickness. The lower ends of the first support shafts 430 may be fixed to the upper surfaces of both ends of the second support plate 440 in the second direction. A through hole for disposing the second support shaft 470 may be formed in the center of the second support plate 440.

In an embodiment, the third support plates 450 may be connected to the lower surface of the second support plate 440 and support the second support plate 440. The third support plate 450 may be provided as a plate with a predetermined thickness, and one end thereof may be connected to the lower surface of the second support plate 440. In other words, the third support plate 450 may be extended downward from the lower surface of the second support plate 440. There may be a plurality of third support plates 450, where the plurality of third support plates 450 may be connected to the lower surfaces of both ends of the second support plate 440, respectively. A plurality of third support plates 450 may be connected to the lower surfaces of both ends of the second support plate 440 in the second direction.

In an embodiment, the fourth support plate 460 may be disposed under the third support plates 450 to support the third support plates 450. In other words, the other ends of the third support plates 450 may be fixed to the upper surface of the fourth support plate 460, where the fourth support plate 460 may be provided as a plate extending in the first direction with a predetermined thickness. The other ends of the third support plates 450 may be fixed to the upper surfaces of both ends of the fourth support plate 460 in the second direction.

In an embodiment, the second support shaft 470 may be connected to the lower surface of the first support plate 420 and the upper surface of the fourth support plate 460 to support the first support plate 420. The second support shaft 470 may be provided as a circular rod with a predetermined diameter. The upper end may be connected to the lower surface of the first support plate 420, and the lower end may be connected to the upper surface of the fourth support plate 460. In other words, the second support shaft 470 may be extended downward from the lower surface of the first support plate 420 and may be connected to the upper surface of the fourth support plate 460. The upper end of the second support shaft 470 may be connected to the center of the lower surface of the first support plate 420. In other words, the upper end of the second support shaft 470 may be connected to the lower surface of the first support plate 420 directly below the horizontal moving portion 410. The second support shaft 470 may be disposed between the plurality of first support shafts 430 and may penetrate through the second support plate 440 and may be connected to the first support plate 420 and the fourth support plate 460.

In an embodiment, the alignment module 500 may support the lower jig 300 and may move the lower jig 300 so that the lower material 30 is aligned on the lower side of the upper material 20. The alignment module 500 may include a first alignment shaft 510, a first alignment plate 520, a second alignment shaft 530, a second alignment plate 540, an alignment driver 550, a third alignment plate 560, and a damper 570.

In an embodiment, the first alignment shaft 510 may be connected to the lower surface of the lower jig 300 and support the lower jig 300. The first alignment shaft 510 may be provided as a circular rod having a predetermined diameter, and the upper end may be connected to the lower surface of the lower jig 300. In other words, the first alignment shaft 510 may be extended downward from the lower surface of the lower jig 300. There may be a plurality of first alignment shaft 510. The plurality of first alignment shafts 510 may be connected to the lower surfaces of both ends of the lower jig 300, respectively. The plurality of first alignment shafts 510 may be connected to the lower surfaces of both ends of the lower jig 300 in the first direction. Since the first alignment shafts 510 are connected to both ends of the lower jig 300 in the first direction such that they are spaced apart from each other, the support module 400 may be disposed between the first alignment shafts 510.

In an embodiment, the first alignment plate 520 may be disposed under the first alignment shafts 510 to support the first alignment shafts 510. In other words, the lower ends of the first alignment shafts 510 may be fixed to the upper surface of the first alignment plate 520. The first alignment plate 520 may be provided as a plate extended in the first direction with a predetermined thickness. The lower ends of the first alignment shafts 510 may be fixed to the upper surfaces of both ends of the first alignment plate 520 in the first direction. A through hole for disposing the second support shaft 470 may be formed in the center of the first alignment plate 520.

In an embodiment, the second alignment shaft 530 may be connected to the lower surface of the first alignment plate 520 and support the first alignment plate 520. The second alignment shaft 530 may be provided as a circular rod with a predetermined diameter, and the upper end may be connected to the lower surface of the first alignment plate 520. In other words, the second alignment shaft 530 may be extended downward from the lower surface of the first alignment plate 520. There may be a plurality of second alignment shafts 530. The plurality of second alignment shafts 530 may be connected along the edges of the lower surface of the first alignment plate 520. For example, the first alignment plate 520 may be provided as a rectangular plate, and the upper ends of the second alignment shafts 530 may be connected to the lower surfaces disposed adjacent to the vertices of the first alignment plate 520.

In an embodiment, the second alignment plate 540 may be disposed under the second alignment shafts 530 to support the second alignment shafts 530. In other words, the lower ends of the second alignment shafts 530 may be fixed to the upper surface of the second alignment plate 540. The second alignment plate 540 may be provided as a plate extended in the second direction with a predetermined thickness. The lower ends of the second alignment shafts 530 may be connected along the edges of the upper surface of the second alignment plate 540. For example, the second alignment plate 540 may be provided as a rectangular plate, and the lower ends of the second alignment shafts 530 may be connected to the upper surfaces disposed adjacent to the vertices of the second alignment plate 540. A through hole for disposing the second support shaft 470 may be formed in the center of the second alignment plate 540. The lower surface of the second alignment plate 540 may be connected to the alignment driver 550.

In an embodiment, the alignment driver 550 may be connected to the lower jig 300 by the first alignment shafts 510, the first alignment plate 520, the second alignment shaft 530, and the second alignment plate 540. The alignment driver 550 may be connected to the second alignment plate 540 to move the second alignment plate 540, and the lower jig 300 may be moved as the second alignment plate 540 connected to the lower jig 300 moves by the first alignment shafts 510, the first alignment plate 520 and the second alignment shaft 530. The alignment driver 550 may be implemented as an alignment stage. Such an alignment stage is well known in the art and thus will not be described herein.

In an embodiment, the third alignment plate 560 may be disposed under the alignment driver 550 to support the alignment driver 550. In other words, the alignment driver 550 may be fixed to the upper surface of the third alignment plate 560, where the third alignment plate 560 may be provided as a plate with a predetermined thickness.

In an embodiment, the damper 570 may be disposed under the third alignment plate 560 and may mitigate the load applied to the alignment driver 550. For example, the damper 570 may be provided as a cylinder. The drive shaft of the cylinder may be connected to the lower surface of the third alignment plate 560, and the body of the cylinder may be fixed to the upper surface of the fourth support plate 460. When the load generated when pressing the upper material 20 against the lower material 30 is applied to the alignment driver 550, the drive shaft of the cylinder may move downward to mitigate the load applied to the alignment driver 550. There may be a plurality of dampers 570 such that they are spaced apart from each other.

Hereinafter, the operation of the bonding apparatus 10, according to an embodiment, will be described with reference to the drawings.

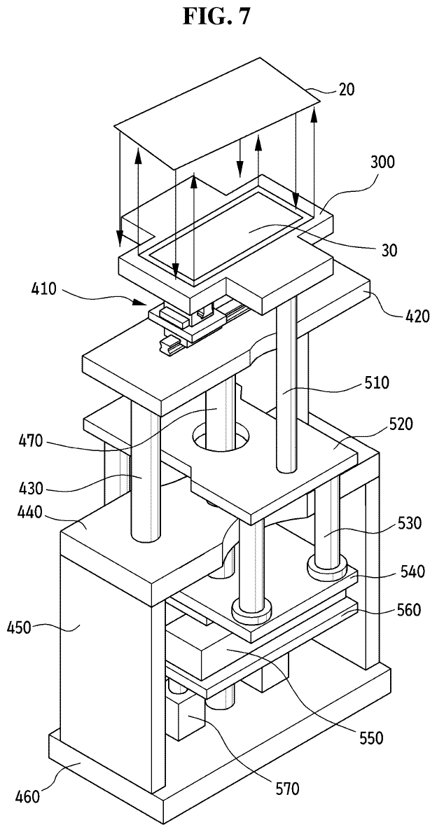

FIG. 7 is a view showing a state in which the lower material 30 is seated on the lower jig 300 of FIG. 2 and the upper material 20 is positioned on the lower material 30, according to an embodiment.

In an embodiment and referring to FIG. 7, it can be seen that the lower material 30 is not properly aligned on the lower side of the upper material 20. In this instance, a separate vision camera (not shown) captures each vertex of the upper material 20 and each vertex of the lower material 30 and transmits the images to a controller (not shown). The controller analyzes the images transmitted by the vision camera. If the vertices of the upper material 20 and the vertices of the lower material 30 are not located on the same lines, respectively, the controller may operate the alignment driver 550 to move the lower jig 300.

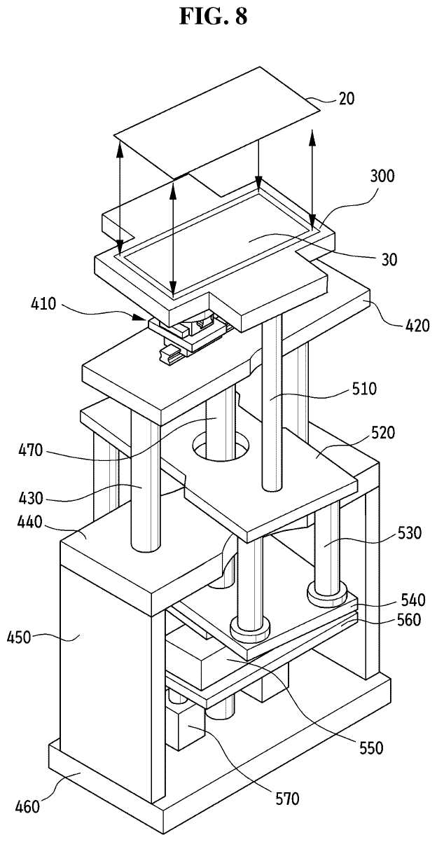

FIG. 8 is a view showing a state in which the lower material 30 is aligned on the lower side of the upper material 20 by the alignment module 500 in FIG. 7, according to an embodiment.

In an embodiment and referring to FIG. 8, the lower jig 300 may be moved by the operation of the alignment driver 550. The vision camera may continuously capture the upper material 20 and the lower material 30 while the lower jig 300 is moving and transmit the images to the controller. The controller analyzes the images transmitted by the vision camera. When the vertices of the upper material 20 and the vertices of the lower material 30 are located on the same lines, respectively, the controller may interrupt the operation of the alignment driver 550.

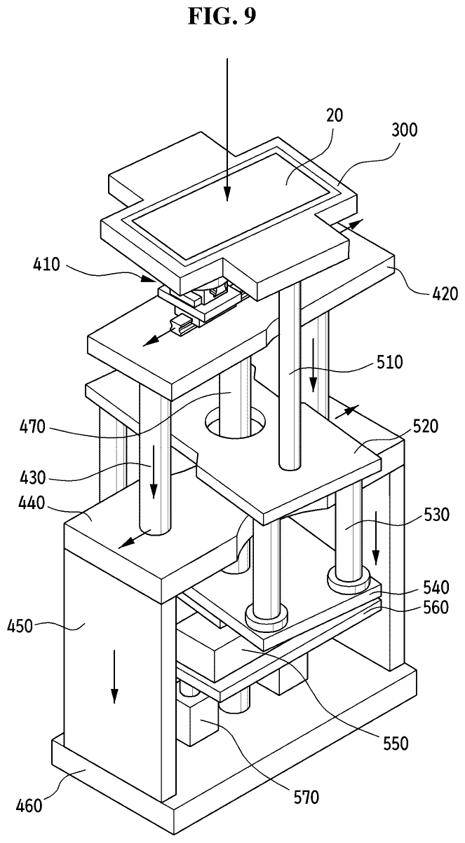

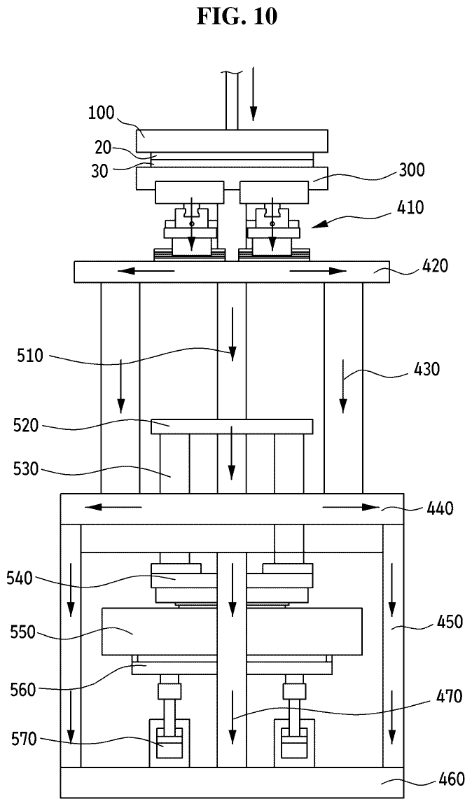

FIG. 9 is a view showing a state in which the upper material 20 presses the lower material 30 in FIG. 8, according to an embodiment. FIG. 10 is a view showing a state in which the load generated by being pressed by the upper material 20 in FIG. 9 is distributed, according to an embodiment.

In an embodiment and referring to FIGS. 9 and 10, when it is determined that the lower material 30 is aligned on the lower side of the upper material 20, the controller may operate the actuator 240 to move the upper material 20 downward to press the lower material 30. By doing so, the upper material 20 and the lower material 30 may be attached together. As the upper material 20 presses the lower material 30, a load is generated. The generated load may be distributed in the directions of the arrows in FIGS. 9 and 10.

In an embodiment, as the support module 400 and the alignment module 500 independently support the lower jig 300, and the support module 400 supports the center of the lower jig 300, most of the load generated when the upper material 20 presses the lower material 30 may be applied to the support module 400 and distributed. Even though the load generated when the upper material 20 presses the lower material 30 may be applied also to the alignment module 500, the alignment module 500 supports the edges of the lower jig 300, not the center, and thus the load may be applied less than the support module 400. In addition, since the load applied to the alignment module 500 can be mitigated by the damper 570, only a very small amount of the load may be applied to the alignment driver 550. Therefore, the bonding apparatus 10, according to an embodiment, can prevent the alignment driver 550 from being damaged by the load generated when the upper material 20 and the lower material 30 are attached together.

It should be understood, that the aspects and features of embodiments of the invention are not restricted to the one set forth herein. The above and other aspects of the invention will become more apparent to one of ordinary skill in the art to which the invention pertains. Thus, it will be understood by one of ordinary skill in the art to which the invention belongs that the invention may be implemented in other specific embodiments than those described herein without changing the technical spirit or essential features of the invention. Therefore, it is to be understood that the exemplary embodiments described above are illustrative rather than being restrictive in all aspects. The disclosed embodiments of the invention are used in a generic and descriptive sense only and not for purposes of limitation. Each component specifically shown in the embodiments of the invention can be implemented by modification, and such modifications and differences related to invention should be construed as being included in the scope of the invention. Moreover, the embodiments or parts of the embodiments may be combined in whole or in part without departing from the scope of the invention.

What is claimed is:

1. A bonding apparatus comprising:
an upper jig supporting an upper material;
a movement module configured to move the upper jig in a vertical direction;
a lower jig disposed below the upper jig and supporting a lower material;
a support module supporting the lower jig; and
an alignment module configured to support the lower jig and to move the lower jig so that the lower material is aligned with a lower side of the upper material,
wherein the support module and the alignment module support the lower jig independently of each other.

2. The apparatus of claim 1, wherein the support module comprises
a horizontal moving portion which moves the lower jig in a horizontal direction and connected to a lower portion of the lower jig; and
a first support plate supporting the horizontal moving portion.

3. The apparatus of claim 2, wherein the horizontal moving portion comprises
a first rail disposed on an upper surface of the first support plate and extending in a first direction;
a first block moved along the first rail;
a second rail connected to the lower jig and extending in a second direction; and
a second block moved along the second rail.

4. The apparatus of claim 3, wherein the second block is disposed on an upper side of the first block, and wherein the second rail is disposed on an upper side of the second block.

5. The apparatus of claim 4, wherein the horizontal moving unit further comprises a base member disposed between the first block and the second block.

6. The apparatus of claim 3, wherein the second direction is directed in a direction that is orthogonal to the first direction.

7. The apparatus of claim 3, wherein the horizontal moving portion further comprises a rotating member disposed between the lower jig and the second rail, wherein the rotating member rotates the lower jig in the horizontal direction.

8. The apparatus of claim 2, wherein the horizontal moving portion is connected to a center of the lower jig.

9. The apparatus of claim 2, wherein the support module further comprises
at least one first support shaft supporting the first support plate and connected to a lower portion of the first support plate;
a second support plate supporting the at least one first support shaft;
a third support plate supporting the second support plate and connected to a lower portion of the second support plate; and
a fourth support plate supporting the third support plate.

10. The apparatus of claim 9, wherein the support module further comprises a second support shaft connected to the lower portion of the first support plate and an upper portion of the fourth support plate to support the first support plate.

11. The apparatus of claim 10, wherein the second support shaft is connected to the lower portion of the first support plate on a lower side of the horizontal moving portion.

12. The apparatus of claim 10, wherein the at least one first support shaft comprises a plurality of first support shafts, and wherein the plurality of first support shafts are connected to lower portions of both edges of the first support plate so that the second support shaft is located between the plurality of first support shafts.

13. The apparatus of claim 1, wherein the alignment module comprises at least one first alignment shaft supporting the lower jig and connected to a lower portion of the lower jig; and an alignment driver connected to the first alignment shaft to move the lower jig.

14. The apparatus of claim 13, wherein the at least one first alignment shaft comprises a plurality of first alignment shafts, and wherein the plurality of first alignment shafts are connected to lower portions of both edges of the lower jig so that the support module is located between the plurality of first alignment shafts.

15. The apparatus of claim 13, wherein the alignment module further comprises
a first alignment plate supporting the first alignment shaft;
at least one second alignment shaft connected to a lower portion of the first alignment plate and supporting the first alignment plate; and
a second alignment plate disposed above the alignment driver and supporting the at least one second alignment shaft.

16. The apparatus of claim 15, wherein the at least one second alignment shaft comprises a plurality of second alignment shafts, and wherein the plurality of second alignment shafts are connected along lower position of edges of the first alignment plate.

17. The apparatus of claim 13, wherein the alignment module further comprises a damper disposed under the alignment driver.

18. The apparatus of claim 17, wherein the alignment module further comprises a third alignment plate disposed between the alignment driver and the damper to support the alignment driver.

19. The apparatus of claim 1, wherein the support module is connected to a center of the lower jig, and wherein the alignment module is connected to the lower portion of the lower jig such that the alignment module is spaced apart from the support module.

20. The apparatus of claim 19. wherein the alignment module is connected to lower portions of edges of the lower jig.
